(19) United States
(12) Patent Application Publication
(10) Pub. No.: US 2023/0048675 A1
(43) Pub. Date: Feb. 16, 2023

(54) LIGHT-EMITTING APPARATUS

(71) Applicant: SONY SEMICONDUCTOR SOLUTIONS CORPORATION, Kanagawa (JP)

(72) Inventors: Takashi SAKAIRI, Kanagawa (JP); Atsushi YAMAMOTO, Kanagawa (JP); Kensaku MAEDA, Kanagawa (JP)

(73) Assignee: SONY SEMICONDUCTOR SOLUTIONS CORPORATION, Kanagawa (JP)

(21) Appl. No.: 17/792,016

(22) PCT Filed: Dec. 10, 2020
(86) PCT No.: PCT/JP2020/046016

§ 371 Date: Jul. 11, 2022

(30) Foreign Application Priority Data
Jan. 20, 2020 (JP) 2020-006963

(51) Int. Cl. G02F 1/29; G01S 17/89; G01S 17/10

(52) U.S. Cl. CPC G02F 1/29; G01S 17/89; G01S 17/10

(57) ABSTRACT

To provide a light-emitting apparatus capable of suitably controlling light emitted from a light-emitting element. A light-emitting apparatus according to the present disclosure includes: a substrate; a plurality of light-emitting elements which are provided on a side of a first surface of the substrate; and an optical element which is provided on a side of a second surface of the substrate and into which light emitted from the plurality of light-emitting elements is incident, wherein the optical element includes a liquid crystal layer which is configured to function as a lens.

### TECHNICAL FIELD

An embodiment of the present disclosure relates to a light-emitting apparatus.

### BACKGROUND ART

Surface-emitting lasers such as a VCSEL (Vertical Cavity Surface Emitting Laser) are known as a type of semiconductor laser. Generally, in a light-emitting apparatus using a surface-emitting laser, a plurality of light-emitting elements are provided in a two-dimensional array pattern on a front surface or a rear surface of a substrate.

### CITATION LIST

### Patent Literature

[PTL 1]

Japanese Translation of PCT Application No. 2004-526194

### SUMMARY

### Technical Problem

In a light-emitting apparatus such as that described above, for example, light emitted from the light-emitting elements must be controlled by an optical element such as a lens. In this case, determining what kind of optical element to use for suitably controlling light is an important issue.

In consideration thereof, the present disclosure provides a light-emitting apparatus capable of suitably controlling light emitted from a light-emitting element.

### Solution to Problem

A light-emitting apparatus according to a first aspect of the present disclosure includes: a substrate; a plurality of light-emitting elements which are provided on a side of a first surface of the substrate; and an optical element which is provided on a side of a second surface of the substrate and into which light emitted from the plurality of light-emitting elements is incident, wherein the optical element includes a liquid crystal layer which is configured to function as a lens. Accordingly, light can be controlled by a lens realized by the liquid crystal layer and, for example, a property of the lens can be changed by driving of the liquid crystal layer.

In addition, in the first aspect, the optical element may include a first optical element into which light emitted from the plurality of light-emitting elements is incident and a second optical element into which light having passed through the first optical element is incident, wherein at least any of the first and second optical elements may include a liquid crystal layer which is configured to function as a lens. Accordingly, light from the plurality of light-emitting elements can be suitably controlled by the first and second optical elements.

Furthermore, in the first aspect, the first optical element may include a liquid crystal layer which is configured to function as a plurality of first lenses into which light emitted from the plurality of light-emitting elements is incident, and the second optical element may include a liquid crystal layer which is configured to function as a second lens into which light having passed through the plurality of first lenses is incident. Accordingly, for example, light from the plurality of light-emitting elements can be suitably shaped by the first and second lenses.

Moreover, in the first aspect, the first optical element may include a liquid crystal layer which is configured to function as a plurality of first lenses into which light emitted from the plurality of light-emitting elements is incident, and the second optical element may include a non-liquid crystal second lens into which light having passed through the plurality of first lenses is incident. Accordingly, for example, light from the plurality of light-emitting elements can be suitably shaped by the first and second lenses.

In addition, in the first aspect, the first optical element may include a plurality of non-liquid crystal first lenses into which light emitted from the plurality of light-emitting elements is incident, and the second optical element may include a liquid crystal layer which is configured to function as a second lens into which light having passed through the plurality of first lenses is incident. Accordingly, for example, light from the plurality of light-emitting elements can be suitably shaped by the first and second lenses.

Furthermore, in the first aspect, the optical element may include a first electrode which is provided on a side of the substrate of the liquid crystal layer and a second electrode which is provided on an opposite side to the substrate of the liquid crystal layer. Accordingly, the liquid crystal layer can be driven by the first and second electrodes.

Moreover, in the first aspect, the first or second electrode may include a plurality of electrodes having an annular shape. Accordingly, for example, the liquid crystal layer can be readily made to function as a lens.

In addition, in the first aspect, the first or second electrode may include a plurality of electrodes arranged in a square lattice shape. Accordingly, for example, the liquid crystal layer can be readily made to function as a lens.

Furthermore, in the first aspect, the liquid crystal layer may be sandwiched between first and second substrates and a lens may be provided on a surface of at least any of the first and second substrates. Accordingly, light from the plurality of light-emitting elements can be further shaped by the lens.

Moreover, in the first aspect, the liquid crystal layer may be divided into a plurality of regions and sealed so as to correspond one-to-one to the plurality of light-emitting elements. Accordingly, for example, the liquid crystal layer can be more readily controlled for each individual light-emitting element.

In addition, in the first aspect, the liquid crystal layer may be divided into a plurality of regions and sealed, the number of the plurality of regions being smaller than the number of the plurality of light-emitting elements. Accordingly, for example, light from two or more light-emitting elements can be controlled by a single large lens in the liquid crystal layer.

Furthermore, in the first aspect, the substrate may be a semiconductor substrate containing gallium (Ga) and arsenic (As). Accordingly, a substrate suitable for the light-emitting apparatus can be provided.

Moreover, in the first aspect, light emitted from the plurality of light-emitting elements may be transmitted inside the substrate from the first surface to the second surface and may be incident to the optical element. Accordingly, a structure can be realized in which light is transmitted through the substrate and emitted from the light-emitting apparatus.

In addition, in the first aspect, the first surface of the substrate may be a front surface of the substrate and the second surface of the substrate may be a rear surface of the substrate. Accordingly, a backside illumination-type light-emitting apparatus can be provided.

Furthermore, the light-emitting apparatus according to the first aspect may further include a drive apparatus which is provided on the side of the first surface of the substrate via the plurality of light-emitting elements and which is configured to drive the plurality of light-emitting elements. Accordingly, for example, the substrate provided with the light-emitting elements can be loaded onto the drive apparatus.

Moreover, in the first aspect, the drive apparatus may be configured to drive the plurality of light-emitting elements on an individual basis. Accordingly, light emitted from the plurality of light-emitting elements can be controlled more precisely.

In addition, in the first aspect, the drive apparatus may be further configured to drive the liquid crystal layer. Accordingly, the drive apparatus for the light-emitting elements can also be used for the liquid crystal layer.

Furthermore, in the first aspect, the second optical element may be configured to receive light having passed through the first optical element and reflected by a mirror, reflect light having passed through the first optical element, or receive light having passed through the first optical element and having passed through a mirror. Accordingly, control of light between the first optical element and the second optical element and a positional relationship between the first optical element and the second optical element can be freely designed.

A light-emitting apparatus according to a second aspect of the present disclosure includes: a substrate; a light-emitting element which is provided on a side of a first surface of the substrate; and an optical element which is provided on a side of a second surface of the substrate and into which light emitted from the light-emitting element is incident, wherein the optical element includes a liquid crystal layer which is configured to function as a diffraction grating. Accordingly, light can be controlled by a diffraction grating realized by the liquid crystal layer and, for example, a property of the diffraction grating can be changed by driving of the liquid crystal layer.

In addition, in the second aspect, the optical element may include a first electrode which is provided on a side of the substrate of the liquid crystal layer and a second electrode which is provided on an opposite side to the substrate of the liquid crystal layer. Accordingly, the liquid crystal layer can be driven by the first and second electrodes.

Furthermore, in the second aspect, the first or second electrode may include a plurality of line-shaped electrodes which are arranged parallel to each other. Accordingly, for example, the liquid crystal layer can be readily made to function as a diffraction grating.

Moreover, in the second aspect, the liquid crystal layer may have a first surface which is positioned on a side of the substrate, a second surface which is positioned on an opposite side to the substrate, and a third surface which is positioned between the first surface and the second surface, wherein the optical element may include first and second electrodes which are provided so as to sandwich the liquid crystal layer on the third surface of the liquid crystal layer. Accordingly, the liquid crystal layer can be driven by the first and second electrodes. Furthermore, the first and second electrodes can be arranged at, for example, positions which are far from an optical path of light from the light-emitting element.

A light-emitting apparatus according to a third aspect of the present disclosure includes: a substrate; a light-emitting element which is provided on a side of a first surface of the substrate; and an optical element which is provided on a side of a second surface of the substrate and into which light emitted from the light-emitting element is incident, wherein the optical element includes a liquid crystal layer which is configured to function as a light shutter. Accordingly, light can be controlled by a light shutter which is realized by the liquid crystal layer and, for example, a property of the light shutter can be changed by driving of the liquid crystal layer.

In addition, in the third aspect, the light-emitting apparatus may control on/off of light emitted from the light-emitting apparatus by controlling on/off of the light shutter while continuously emitting light from the light-emitting element. Accordingly, on/off of light can be controlled by driving of the liquid crystal layer.

### BRIEF DESCRIPTION OF DRAWINGS

FIG. 1 is a block diagram showing a configuration of a ranging apparatus according to a first embodiment.

FIG. 2 is a sectional view showing an example of a structure of the ranging apparatus according to the first embodiment.

FIG. 3 is a sectional view showing the structure of the ranging apparatus shown in B in FIG. 2.

FIG. 4 is a sectional view showing a structure of a light-emitting apparatus according to the first embodiment.

FIG. 5 is a plan view showing an example of a structure of a lower optical element shown in FIG. 4.

FIG. 6 is a plan view showing an example of a structure of a lower electrode shown in FIG. 4.

FIG. 7 is a sectional view showing a structure of a light-emitting apparatus according to a modification of the first embodiment.

FIG. 8 is a sectional view showing a structure of a light-emitting apparatus according to another modification of the first embodiment.

FIG. 9 is a sectional view showing a structure of a light-emitting apparatus according to another modification of the first embodiment.

FIG. 10 is a sectional view showing a structure of a light-emitting apparatus according to another modification of the first embodiment.

FIG. 11 is a plan view showing an example of a structure of a lower optical element shown in FIG. 10.

FIG. 12 is a sectional view showing a structure of a light-emitting apparatus according to another modification of the first embodiment.

FIG. 13 is a plan view showing an example of a structure of a lower optical element shown in FIG. 12.

FIG. 14 is a plan view showing various examples of the structure of the lower optical element shown in FIG. 4.

FIG. 15 is a sectional view showing a structure of a light-emitting apparatus according to a second embodiment.

FIG. 16 is a plan view showing an example of a structure of a lower electrode shown in FIG. 15.

FIG. 17 is a plan view showing a structure of an upper optical element according to a modification of the second embodiment.

FIG. 18 is a sectional view showing a structure of a light-emitting apparatus according to a third embodiment.

FIG. 19 is a timing chart showing an operation example of the light-emitting apparatus according to the third embodiment.

FIG. 20 is a sectional view showing structures of light-emitting apparatuses according to various modifications of the first embodiment.

### DESCRIPTION OF EMBODIMENTS

Hereinafter, embodiments of the present invention will be described with reference to drawings.

### First Embodiment

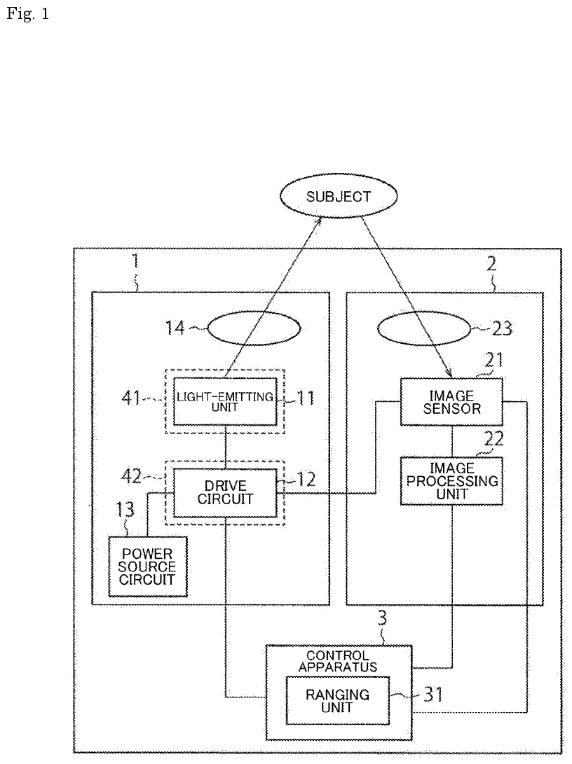

FIG. 1 is a block diagram showing a configuration of a ranging apparatus according to a first embodiment.

The ranging apparatus shown in FIG. 1 includes a light-emitting apparatus 1, an imaging apparatus 2, and a control apparatus 3. The ranging apparatus shown in FIG. 1 irradiates a subject with light emitted from the light-emitting apparatus 1, images the subject by receiving, with the imaging apparatus 2, light reflected by the subject, and measures (calculates) a distance to the subject with the control apparatus 3 using an image signal output from the imaging apparatus 2. The light-emitting apparatus 1 functions as a light source used when the imaging apparatus 2 images a subject.

The light-emitting apparatus 1 includes a light-emitting unit 11, a drive circuit 12, a power source circuit 13, and a light-emitting side optical system 14. The imaging apparatus 2 includes an image sensor 21, an image processing unit 22, and an imaging-side optical system 23. The control apparatus 3 includes a ranging unit 31.

The light-emitting unit 11 emits laser light with which the subject is to be irradiated. As will be described later, the light-emitting unit 11 according to the present embodiment includes a plurality of light-emitting elements arranged in a two-dimensional array pattern and each light-emitting element has a VCSEL structure. The subject is to be irradiated with light emitted from the light-emitting elements. In addition, the light-emitting unit 11 according to the present embodiment is provided inside a chip referred to as an LD (Laser Diode) chip 41.

The drive circuit 12 is an electrical circuit for driving the light-emitting unit 11. The power source circuit 13 is an electrical circuit for generating power supply voltage of the drive circuit 12. For example, the ranging apparatus according to the present embodiment generates power supply voltage with the power source circuit 13 from input voltage supplied from a battery inside the ranging apparatus and drives the light-emitting unit 11 with the drive circuit 12 using the power supply voltage. In addition, the drive circuit 12 according to the present embodiment is provided inside a substrate referred to as an LDD (Laser Diode Driver) substrate 42.

The light-emitting side optical system 14 includes various optical elements and irradiates the subject with light from the light-emitting unit 11 via the optical elements. In a similar manner, the imaging-side optical system 23 includes various optical elements and receives light from the subject via the optical elements.

The image sensor 21 receives light from the subject via the imaging-side optical system 23 and converts the light into an electric signal by photoelectric conversion. For example, the image sensor 21 is a CCD (Charge Coupled Device) sensor or a CMOS (Complementary Metal Oxide Semiconductor) sensor. The image sensor 21 according to the present embodiment converts the electronic signal described above into a digital signal from an analog signal by A/D (Analog to Digital) conversion and outputs an image signal as a digital signal to the image processing unit 22. In addition, the image sensor 21 according to the present embodiment outputs a frame synchronization signal to the drive circuit 12 and, based on the frame synchronization signal, the drive circuit 12 causes the light-emitting unit 11 to emit light at a timing in accordance with a frame period in the image sensor 21.

The image processing unit 22 performs various types of image processing on the image signal output from the image sensor 21. For example, the image processing unit 22 includes an image processing processor such as a DSP (Digital Signal Processor).

The control apparatus 3 controls various operations of the ranging apparatus shown in FIG. 1 such as a light emission operation of the light-emitting apparatus 1 and an imaging operation of the imaging apparatus 2. For example, the control apparatus 3 includes a CPU (Central Processing Unit), a ROM (Read Only Memory), a RAM (Random Access Memory), and the like.

The ranging unit 31 measures a distance to the subject based on an image signal which is output from the image sensor 21 and which has been subjected to image processing by the image processing unit 22. As a ranging method, for example, the ranging unit 31 adopts an STL (Structured Light) method or a ToF (Time of Flight) method. The ranging unit 31 may further specify a three-dimensional shape of the subject by measuring, based on the image signal described above, a distance between the ranging apparatus and the subject for each portion of the subject.

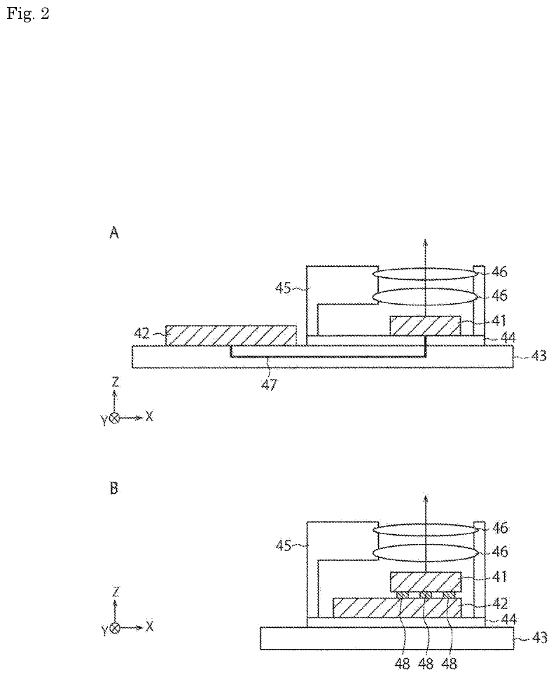

FIG. 2 is a sectional view showing an example of a structure of the ranging apparatus according to the first embodiment.

A in FIG. 2 shows a first example of the structure of the ranging apparatus according to the first embodiment. The ranging apparatus according to the example includes the LD chip 41 and the LDD substrate 42 described above, a mounting substrate 43, a heat dissipation substrate 44, a correcting lens holding unit 45, one or more correcting lenses 46, and wiring 47.

A in FIG. 2 shows an X axis, a Y axis, and a Z axis which are perpendicular to each other. An X direction and a Y direction correspond to a lateral direction (horizontal direction) and a Z direction corresponds to a longitudinal direction (a perpendicular direction). In addition, a +Z direction corresponds to an upward direction and a −Z direction corresponds to a downward direction. The −Z direction may strictly coincide with the direction of gravitational force or may not strictly coincide with the direction of gravitational force.

The LD chip 41 is arranged on the mounting substrate 43 via the heat dissipation substrate 44 and the LDD substrate 42 is also arranged on the mounting substrate 43. The mounting substrate 43 is, for example, a printed circuit board. The image sensor 21 and the image processing unit 22 shown in FIG. 1 are also arranged on the mounting substrate 43 according to the present embodiment. The heat dissipation substrate 44 is, for example, a ceramic substrate such as an AlN (aluminum nitride) substrate.

The correcting lens holding unit 45 is arranged on the heat dissipation substrate 44 so as to surround the LD chip 41 and holds one or more correcting lenses 46 above the LD chip 41. The correcting lenses 46 are included in the light-emitting side optical system 14 (FIG. 1) described above. Light emitted from the light-emitting unit 11 (FIG. 1) inside the LD chip 41 is corrected by the correcting lenses 46 and, subsequently, the subject (FIG. 1) is irradiated with the corrected light. As an example, A in FIG. 2 shows two correcting lenses 46 being held by the correcting lens holding unit 45.

The wiring 47 is provided on a front surface and a rear surface of the mounting substrate 41, provided inside the mounting substrate 41, and the like and electrically connects the LD chip 41 and the LDD substrate 42 to each other. The wiring 47 is, for example, printed wiring which is provided on the front surface and the rear surface of the mounting substrate 41 or via wiring which penetrates the mounting substrate 41. The wiring 47 according to the present embodiment further passes inside or near the heat dissipation substrate 44.

B in FIG. 2 shows a second example of the structure of the ranging apparatus according to the present embodiment. While the ranging apparatus according to the present example includes the same components as the ranging apparatus according to the first example, the ranging apparatus according to the second example includes a bump 48 instead of the wiring 47.

In B in FIG. 2, the LDD substrate 42 is arranged on the heat dissipation substrate 44 and the LD chip 41 is arranged on the LDD substrate 42. By arranging the LD chip 41 on the LDD substrate 42 in this manner, the mounting substrate 44 can be downsized as compared to the first example. In B in FIG. 2, the LD chip 41 is arranged on the LDD substrate 42 via the bump 48 and the LD chip 41 is electrically connected to the LDD substrate 42 by the bump 48.

Hereinafter, the ranging apparatus according to the present embodiment will be described on the assumption that the ranging apparatus has the structure according to the second example shown in B in FIG. 2. However, with the exception of an explanation of structures specific to the second example, the following explanation is also applicable to a ranging apparatus having the structure according to the first example.

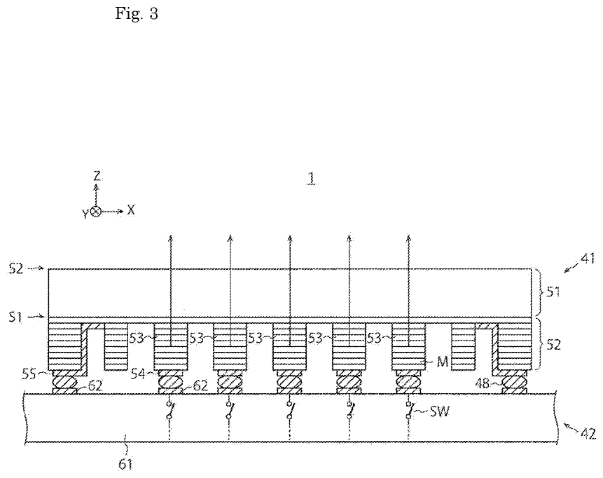

FIG. 3 is a sectional view showing the structure of the ranging apparatus shown in B in FIG. 2.

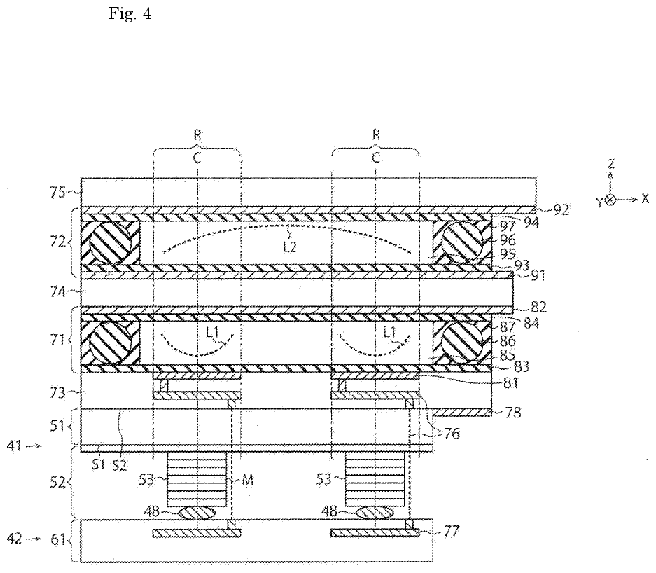

FIG. 3 shows cross sections of the LD chip 41 and the LDD substrate 42 inside the light-emitting apparatus 1. As shown in FIG. 3, the LD chip 41 includes a substrate 51, a laminated film 52, a plurality of light-emitting elements 53, a plurality of anode electrodes 54, and a plurality of cathode electrodes 55. In addition, the LDD substrate 42 includes a substrate 61 and a plurality of connection pads 62. It should be noted that, in FIG. 3, illustration of a lower optical element 71 and an upper optical element 72 (to be described later) has been omitted (refer to FIG. 4).

The substrate 51 is a semiconductor substrate such as a GaAs (gallium arsenide) substrate. FIG. 3 shows a front surface S1 of the substrate 51 facing the −Z direction and a rear surface S2 of the substrate 51 facing the +Z direction. The front surface S1 is an example of the first surface according to the present disclosure. The rear surface S2 is an example of the second surface according to the present disclosure.

The laminated film 52 includes a plurality of layers laminated on the front surface S1 of the substrate 51. Examples of the layers include an n-type semiconductor layer, an active layer, a p-type semiconductor layer, a light reflection layer, and an insulating layer having a light emission window. The laminated film 52 includes a plurality of mesa portions M which protrude in the −Z direction. Apart of the mesa portions M constitutes the plurality of light-emitting elements 53.

The plurality of light-emitting elements 53 are provided on the side of the front surface S1 of the substrate 52 as a part of the laminated film 52. Each light-emitting element 53 according to the present embodiment has a VCSEL structure and emits light in the +Z direction. As shown in FIG. 3, light emitted from each light-emitting element 53 is transmitted inside the substrate 51 from the front surface S1 to the rear surface S2 and enters the correcting lens 46 (FIG. 2) described above from the substrate 51. In this manner, the LD chip 41 according to the present embodiment is configured as a backside illumination-type VCSEL chip.

The anode electrode 54 is formed on a lower surface of the light-emitting elements 53. The cathode electrode 55 is formed on a lower surface of a mesa portion M other than the light-emitting elements 53 and extends to a lower surface of the laminated film 52 between the mesa portions M. Each light-emitting element 53 emits light when a current flows between the anode electrode 54 and a corresponding cathode electrode 55.

As described above, the LD chip 41 is arranged on the LDD substrate 42 via the bump 48 and the LD chip 41 is electrically connected to the LDD substrate 42 by the bump 48. Specifically, the connection pad 62 is formed on the substrate 61 included in the LDD substrate 42 and the mesa portion M is arranged on the connection pad 62 via the bump 48. Each mesa portion M is arranged on the bump 62 via the anode electrode 54 or the cathode electrode 55. The substrate 61 is a semiconductor substrate such as a Si (silicon) substrate.

The LDD substrate 42 includes the drive circuit 12 which drives the light-emitting unit 11 (FIG. 1). FIG. 4 schematically shows a plurality of switches SW included in the drive circuit 12. Each switch SW is electrically connected to a corresponding light-emitting element 53 via the bump 62. The drive circuit 12 according to the present embodiment is capable of controlling (on/off) the switches SW on an individual basis. Therefore, the drive circuit 12 can drive the plurality of light-emitting elements 53 on the basis of each light-emitting element 53. Accordingly, light emitted from the light-emitting unit 11 can be controlled precisely such as causing only the light-emitting elements 53 necessary for ranging to emit light. Such individual control of the light-emitting elements 53 is realized by arranging the LDD substrate 42 below the LD chip 41 to make it easier for each light-emitting element 53 to be electrically connected to the switch SW corresponding to the light-emitting element 53. The LDD substrate 42 is an example of the drive apparatus according to the present disclosure.

FIG. 4 is a sectional view showing a structure of the light-emitting apparatus 1 according to the first embodiment. FIG. 4 shows cross sections of the LD chip 41 and the LDD substrate 42 inside the light-emitting apparatus 1. As described above, the LD chip 41 includes the substrate 51, the laminated film 52, a plurality of the light-emitting elements 53, a plurality of the anode electrodes 54, and a plurality of the cathode electrodes 55, and the LDD substrate 42 includes the substrate 61 and the plurality of connection pads 62. It should be noted that illustration of the anode electrodes 54, the cathode electrodes 55, and the connection pads 62 has been omitted in FIG. 4.

The light-emitting apparatus 1 according to the present embodiment includes the plurality of light-emitting elements 53 on the side of the front surface S1 of the substrate 51 and includes the lower optical element 71, the upper optical element 72, and three substrates 73, 74, and 75 on the side of the rear surface S2 of the substrate 51. The light-emitting apparatus 1 according to the present embodiment further includes a plurality of wirings 76, a plurality of liquid crystal drive units 77, and a liquid crystal drive element 78. The lower optical element 71 and the upper optical element 72 are examples of the optical element according to the present disclosure and are, respectively, examples of the first optical element and the second optical element according to the present disclosure.

The lower optical element 71 is provided between the substrates 73 and 74 and includes a plurality of lower electrodes 81, an upper electrode 82, a lower oriented film 83, an upper oriented film 84, a liquid crystal layer 85, a plurality of gap materials 86, and a liquid crystal seal 87. The lower electrode 81 and the upper electrode 82 are, respectively, examples of the first electrode and the second electrode according to the present disclosure.

The upper optical element 72 is provided between the substrates 74 and 75 and includes a lower electrode 91, an upper electrode 92, a lower oriented film 93, an upper oriented film 94, a liquid crystal layer 95, a plurality of gap materials 96, and a liquid crystal seal 97. The lower electrode 91 and the upper electrode 92 are, respectively, examples of the first electrode and the second electrode according to the present disclosure.

The substrates 73, 74, and 75 are sequentially laminated on the substrate 51 via the lower optical element 71 and the upper optical element 72. The substrates 73, 74, and 75 are, for example, a transparent substrate such as a glass substrate or a quartz substrate. The substrates 73 and 74 are arranged so as to sandwich the lower optical element 71 (specifically, the liquid crystal layer 85), and the substrates 74 and 75 are arranged so as to sandwich the upper optical element 72 (specifically, the liquid crystal layer 95).

The lower electrode 81 is provided on an upper surface of the substrate 73, and the upper electrode 82 is provided on a lower surface of the substrate 74. The lower electrode 81 and the upper electrode 82 are, for example, a transparent electrode such as an ITO (Induim Tin Oxide) electrode. The lower electrode 81 is provided on a side of the substrate 51 of the liquid crystal layer 85 and the upper electrode 82 is provided on an opposite side to the substrate 51 of the liquid crystal layer 85. The lower electrode 81 and the upper electrode 82 are used to drive the liquid crystal layer 85 and, more specifically, used to control an azimuth of liquid crystal molecules inside the liquid crystal layer 85. The lower electrodes 81 according to the present embodiment correspond one-to-one to the light-emitting elements 53, and each lower electrode 81 is arranged in the +Z direction of a corresponding light-emitting element 53. On the other hand, the upper electrode 82 according to the present embodiment is arranged in the +Z direction of the plurality of light-emitting elements 53 and configured as a common electrode which corresponds to the plurality of light-emitting elements 53.

The lower oriented film 83 is provided on the upper surface of the substrate 73 via the lower electrode 81, and the upper oriented film 84 is provided on the lower surface of the substrate 74 via the upper electrode 82. The lower oriented film 83 and the upper oriented film 84 are, for example, a transparent inorganic film such as a silicon oxide film or a transparent organic film such as a polyimide film. The lower oriented film 83 and the upper oriented film 84 according to the present embodiment have a plurality of grooves for orienting liquid crystal molecules inside the liquid crystal layer 85.

The liquid crystal layer 85 is provided between the lower oriented film 83 and the upper oriented film 84. FIG. 4 shows a plurality of lenses L1 which are realized inside the liquid crystal layer 85. The liquid crystal layer 85 according to the present embodiment can function as the lenses L1 by being driven by the lower electrode 81 and the upper electrode 82. The lenses L1 are an example of the first lens according to the present disclosure. The lenses L1 according to the present embodiment correspond one-to-one to the light-emitting elements 53, and each lens L1 is produced in the +Z direction of a corresponding light-emitting element 53. While the lenses L1 are concave lenses in FIG. 4, the lenses L1 may be convex lenses instead.

The gap material 86 is provided between the substrates 73 and 74 in order to maintain a constant gap between the substrates 73 and 74. The gap material 86 is, for example, silica particles. The gap material 86 according to the present embodiment is embedded in the liquid crystal seal 87.

The liquid crystal seal 87 is provided between the substrates 73 and 74 in order to seal the liquid crystal layer 85 between the substrates 73 and 74. A material of the liquid crystal seal 87 is, for example, a resin. The liquid crystal seal 87 according to the present embodiment is provided so as to surround the liquid crystal layer 85 in a ring shape.

The lower electrode 91 is provided on an upper surface of the substrate 74, and the upper electrode 92 is provided on a lower surface of the substrate 75. The lower electrode 91 and the upper electrode 92 are, for example, a transparent electrode such as an ITO electrode. The lower electrode 91 is provided on a side of the substrate 51 of the liquid crystal layer 95 and the upper electrode 92 is provided on an opposite side to the substrate 51 of the liquid crystal layer 95. The lower electrode 91 and the upper electrode 92 are used to drive the liquid crystal layer 95 and, more specifically, used to control an azimuth of liquid crystal molecules inside the liquid crystal layer 95. The lower electrode 91 according to the present embodiment is arranged in the +Z direction of the plurality of light-emitting elements 53 and configured as a common electrode which corresponds to the plurality of light-emitting elements 53. In a similar manner, the upper electrode 92 according to the present embodiment is arranged in the +Z direction of the plurality of light-emitting elements 53 and configured as a common electrode which corresponds to the plurality of light-emitting elements 53.

The lower oriented film 93 is provided on the upper surface of the substrate 74 via the lower electrode 91, and the upper oriented film 94 is provided on the lower surface of the substrate 75 via the upper electrode 92. The lower oriented film 93 and the upper oriented film 94 are, for example, a transparent inorganic film such as a silicon oxide film or a transparent organic film such as a polyimide film. The lower oriented film 93 and the upper oriented film 94 according to the present embodiment have a plurality of grooves for orienting liquid crystal molecules inside the liquid crystal layer 95.

The liquid crystal layer 95 is provided between the lower oriented film 93 and the upper oriented film 94. FIG. 4 shows a lens L2 which is realized inside the liquid crystal layer 95. The liquid crystal layer 95 according to the present embodiment can function as the lens L2 by being driven by the lower electrode 91 and the upper electrode 92. The lens L2 is an example of the second lens according to the present disclosure. The lens L2 according to the present embodiment is a common lens which corresponds to the plurality of light-emitting elements 53 and the lens L2 is produced in the +Z direction of the plurality of light-emitting elements 53. While the lens L2 is a convex lens in FIG. 4, the lens L2 may be a concave lens instead.

The gap material 96 is provided between the substrates 74 and 75 in order to maintain a constant gap between the substrates 74 and 75. The gap material 96 is, for example, silica particles. The gap material 96 according to the present embodiment is embedded in the liquid crystal seal 97.

The liquid crystal seal 97 is provided between the substrates 74 and 75 in order to seal the liquid crystal layer 95 between the substrates 74 and 75. A material of the liquid crystal seal 97 is, for example, a resin. The liquid crystal seal 97 according to the present embodiment is provided so as to surround the liquid crystal layer 95 in a ring shape.

The wiring 76 is provided inside the substrate 73 and the like and electrically connects the lower electrode 81 with the liquid crystal drive unit 78. Each wiring 76 according to the present embodiment electrically connects one lower electrode 81 to the liquid crystal drive unit 78 which corresponds to the lower electrode 81.

The liquid crystal drive unit 77 is a circuit for driving the liquid crystal layer 85 by applying voltage to the lower electrode 81. The liquid crystal drive unit 77 according to the present embodiment is provided inside the substrate 61 and constitutes a part of the LDD substrate 42. Accordingly, the LDD substrate 42 can not only be used for driving the light-emitting elements 53 but also for driving the liquid crystal layer 85. The liquid crystal drive unit 77 according to the present embodiment corresponds one-to-one to the lower electrodes 81 and each liquid crystal drive unit 77 is capable of producing one lens L1 with the corresponding lower electrode 81.

The liquid crystal drive element 78 is an element for driving the liquid crystal layer 85 or the liquid crystal layer 95 by applying voltage to the upper electrode 82, the lower electrode 91, or the upper electrode 92. The liquid crystal drive element 78 according to the present embodiment is provided on the lower surface of the substrate 73. For example, the liquid crystal drive element 78 is capable of producing the lens L2 by applying a drive voltage to the lower electrode 91 or the upper electrode 92.

Light emitted from the plurality of light-emitting elements 53 is transmitted inside the substrate 51 from the front surface S1 to the rear surface S2 and enters the plurality of lenses L1 inside the liquid crystal layer 85. In the present embodiment, light emitted from each light-emitting element 53 is incident to a corresponding lens L1. Light having passed through the lenses L1 is incident to the lens L2 inside the liquid crystal layer 95, and light having passed through the lens L2 is incident to the correcting lens 46 (B in FIG. 2). In the present embodiment, the lenses L1 and L2 diffuse and focus the light from the light-emitting elements 53 and the correcting lens 46 collimates the light from the lenses L1 and L2 to create parallel light. The light having passed through the correcting lens 46 is emitted toward the subject (FIG. 1).

FIG. 4 further shows a plurality of light transmission areas R through which light from each light-emitting element 53 is transmitted and a central axis C which is positioned at center of each light transmission area R. In FIG. 4, the front surface S1 of the substrate 51 is perpendicular to the Z direction and each central axis C is parallel to the Z direction. The lower optical element 71, the upper optical element 72, and the substrates 73, 74, and 75 according to the present embodiment may be configured such that light can be transmitted through portions other than the light transmission areas R or configured so as to include a light-shielding member in portions other than the light transmission areas R.

According to the present embodiment, for example, an aberration of the correcting lens 46 can be reduced by arranging the lenses L1 and L2 between the light-emitting elements 53 and the correcting lens 46. This is because, by diffusing light from the light-emitting elements 53 with the lenses L1 and focusing light from the lenses L1 with the lens L2, light from the light-emitting elements 53 can be more readily collimated by the correcting lens 46. Accordingly, an occurrence of blurring or distortion at ends of an image can be suppressed and a high-resolution imaging apparatus 2 (FIG. 1) can be realized. It should be noted that such an effect can be produced even when the lenses L1 are other than concave lenses and even when the lens L2 is other than a convex lens.

In the present embodiment, the lenses L1 and L2 which produce such an effect are realized by the liquid crystal layers 85 and 95. Accordingly, properties of the lenses L1 and L2 can be changed by driving of the liquid crystal layers 85 and 95 (optically variable lenses). For example, radii, depths, curvatures, and positions of the lenses L1 and L2 and a distance between the lenses L1 can be adjusted to values suitable for collimation by the correcting lens 46. Furthermore, by variously adjusting properties of the lenses L1 and L2, the number of optical elements of the light-emitting apparatus 1 can be reduced and downsizing and weight reduction of the light-emitting apparatus 1 can be realized. In this manner, according to the present embodiment, light emitted from the light-emitting elements 53 can be suitably controlled by the lenses L1 and L2 inside the liquid crystal layers 85 and 95.

While the light-emitting apparatus 1 according to the present embodiment includes two liquid crystal layers 85 and 95, alternatively, the light-emitting apparatus 1 according to the present embodiment may include only one of the liquid crystal layers 85 and 95. For example, when an aberration of the correcting lens 46 can be sufficiently reduced by adjusting the light from the light-emitting elements 53 with only the lenses L1, the light-emitting apparatus 1 may include only the liquid crystal layer 85.

In addition, the lens L2 according to the present embodiment may be used as a lens that substitutes for the correcting lens 46. In this case, either the correcting lenses 46 shown in B in FIG. 2 become unnecessary or the number of the correcting lenses 46 shown in B in FIG. 2 is reduced.

Furthermore, while the lower electrodes 81 and 91 and the upper electrodes 82 and 92 are transparent electrodes such as ITO electrodes in the present embodiment, the lower electrodes 81 and 91 and the upper electrodes 82 and 92 may be electrodes which pass only light with a predetermined wavelength. For example, when a given light-emitting element 53 is provided in order to emit blue light, each electrode for the light-emitting element 53 may be configured to pass only blue light. In addition, when a given light-emitting element 53 is provided in order to emit infrared light, each electrode for the light-emitting element 53 may be configured to pass only infrared light. This description similarly applies to the lower oriented films 83 and 93, the upper oriented films 84 and 94, and the substrates 73, 74, and 75. For example, the lower electrodes 81 and 91 and the upper electrodes 82 and 92 may be semiconductor layers or metallic layers and, specifically, may be thin films made of aluminum (Al) or titanium (Ti).

In addition, in the present embodiment, while the lower electrode 81 is structured as an individual electrode which is provided for each light-emitting element 53 and the upper electrode 82, the lower electrode 91, and the upper electrode 92 are structured as common electrodes which are provided for a plurality of light-emitting elements 53, other structures may be adopted instead. For example, the lower electrode 81 may be structured as a common electrode and the upper electrode 82 may be structured as an individual electrode.

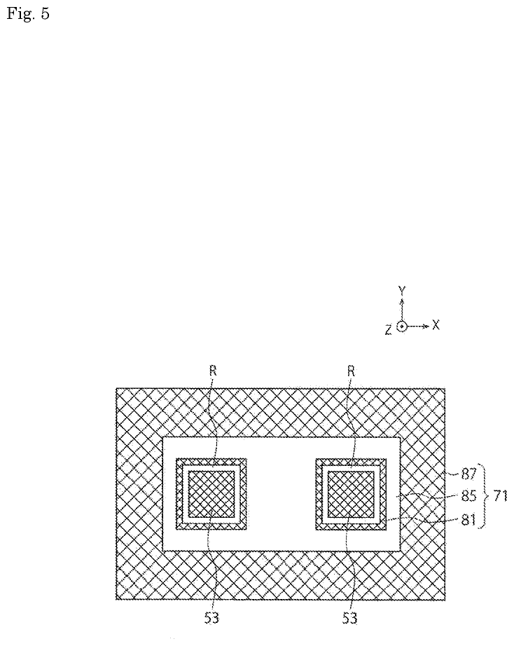

FIG. 5 is a plan view showing an example of a structure of the lower optical element 71 shown in FIG. 4.

FIG. 5 shows a positional relationship among the lower electrode 81 of the lower optical element 71, the liquid crystal layer 85, and the liquid crystal seal 87. FIG. 5 also shows positions of the light-emitting elements 53 and positions of the light transmission areas R.

In a region shown in FIG. 5, the liquid crystal layer 85 for two light-emitting elements 53 is surrounded in a ring shape by the liquid crystal seal 87.

Hereinafter, this region will be referred to as a “unit seal region”. The lower optical element 71 according to the present embodiment includes such a unit seal region in plurality. For example, the lower optical element 71 according to the present embodiment includes four liquid crystal layers 85 for eight light-emitting elements 53 inside four unit seal regions. In this manner, the liquid crystal layers 85 according to the present embodiment are divided into a plurality of unit seal regions and sealed, the number of the plurality of unit seal regions being smaller than the number of the light-emitting elements 53. As will be described later, the number of light-emitting elements 53 per unit seal region may be other than two. The same description applies to the upper optical element 72.

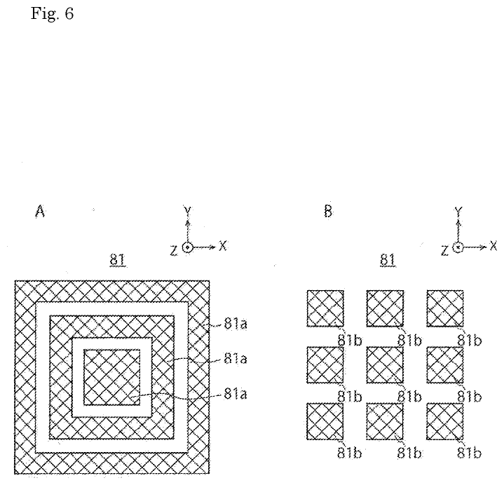

FIG. 6 is a plan view showing examples of a structure of the lower electrode 81 shown in FIG. 4. Each lower electrode 81 according to the present embodiment may be structured as in these examples.

In the example shown in A in FIG. 6, the lower electrode 81 includes a plurality of electrodes 81a which have an annular shape. These electrodes 81a are concentrically arranged around the central axis C described above. Such a lower electrode 81 is useful when, for example, realizing a lens L1 with a shape which is symmetrical with respect to the central axis C. In addition, by providing a resistor between the electrodes 81a, light with gradation can also be output from the lens L1. Desirably, the electrodes 81a can be driven independently of each other. It should be noted that a shape of each electrode 81a may be a shape other than a square (such as a circular shape or an elliptical shape). Furthermore, pitches between the electrodes 81a may differ for each pair of adjacent electrodes 81a and, for example, the farther away from the central axis C, the smaller the pitch.

In the example shown in B in FIG. 6, the lower electrode 81 includes a plurality of electrodes 81b which are arranged in a square lattice shape (a two-dimensional array pattern). Such a lower electrode 81 is useful when, for example, finely controlling the shape of the lens L1. Desirably, the electrodes 81b can be driven independently of each other.

When an electrode other than the lower electrode 81 is to be made an individual electrode, the electrode may be structured as in these examples.

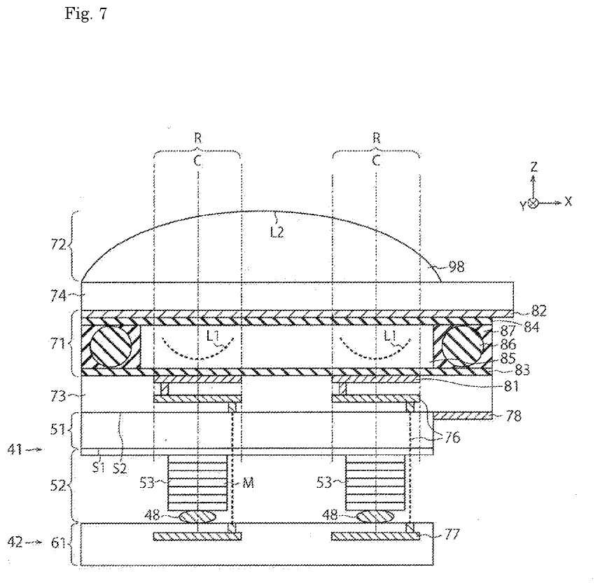

Hereinafter, a light-emitting apparatus 1 according to various modifications of the present embodiment will be described with reference to FIGS. 7 to 14.

FIG. 7 is a sectional view showing a structure of the light-emitting apparatus 1 according to a modification of the first embodiment.

The upper optical element 72 according to the present modification includes a non-liquid crystal lens L2 in place of the liquid crystal layer 95 which functions as the lens L2. The lens L2 according to the present modification is a convex lens which is formed on a surface of a lens film 98. The lens film 98 is, for example, a silicon oxide film. The lens L2 according to the present modification may be a lens (for example, a concave lens) other than a convex lens.

Such a structure can be adopted when, for example, the lens L2 is to be readily formed by machining of the lens film 98.

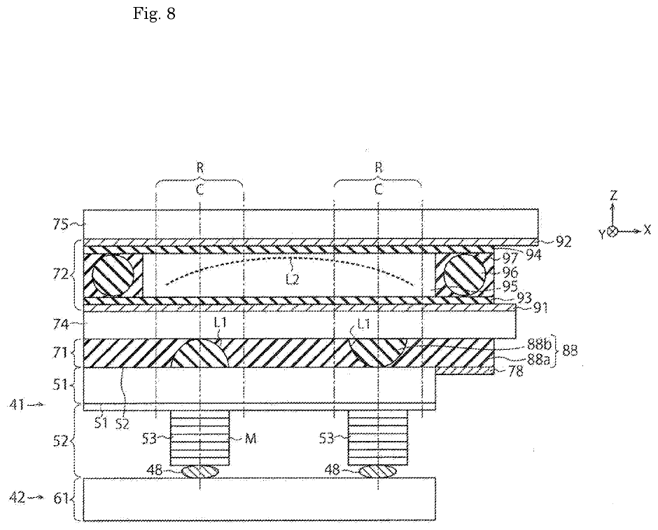

FIG. 8 is a sectional view showing a structure of the light-emitting apparatus 1 according to another modification of the first embodiment.

The lower optical element 71 according to the present modification includes a plurality of non-liquid crystal lenses L1 in place of the liquid crystal layer 85 which functions as a plurality of lenses L1. The lenses L1 according to the present modification are convex lenses or concave lenses which are formed on an interface between a first lens film 88a and a second lens film 88b inside a lens film 88. The first lens film 88a and the second lens film 88b are, for example, transparent films formed of materials that differ from each other. The two lenses L1 shown in FIG. 8 may both be convex lenses, may both be concave lenses, or may be other lenses.

Such a structure can be adopted when, for example, the lenses L1 are to be readily formed by machining of the lens film 88.

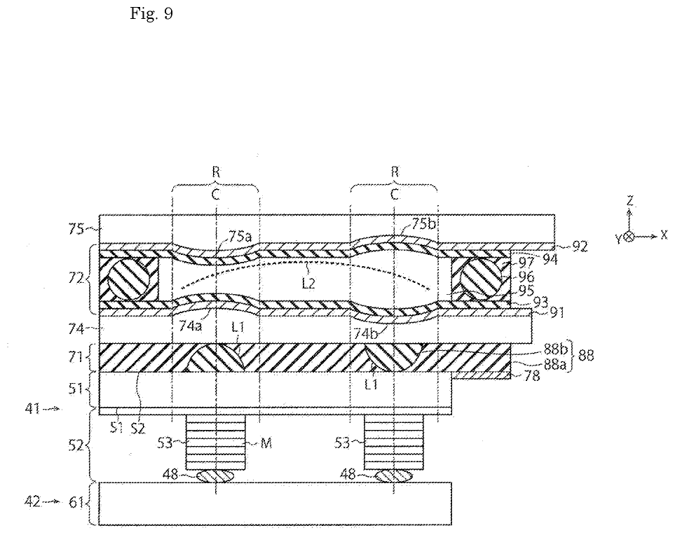

FIG. 9 is a sectional view showing a structure of the light-emitting apparatus 1 according to another modification of the first embodiment.

The lower optical element 71 according to the present modification has a same structure as the lower optical element 71 shown in FIG. 8. On the other hand, the upper optical element 72 according to the present modification is sandwiched between the substrate 74 having a convex portion 74a and a concave portion 74b on an upper surface thereof and the substrate 75 having a convex portion 75a and a concave portion 75b on a lower surface thereof. The substrate 74 is an example of the first substrate according to the present disclosure and the substrate 75 is an example of the second substrate according to the present disclosure.

The convex portions 74a and 75a are arranged in the +Z direction of a left-side light-emitting element 53. The convex portion 74a functions as a convex lens of a stage preceding the lens L2 and the convex portion 75a functions as a concave lens of a stage following the lens L2. A gap between the convex portions 74a and 75a is narrower than gaps in other portions between the substrates 74 and 75.

The concave portions 74b and 75b are arranged in the +Z direction of a right-side light-emitting element 53. The concave portion 74b functions as a concave lens of the stage preceding the lens L2 and the concave portion 75b functions as a convex lens of the stage following the lens L2. A gap between the concave portions 74b and 75b is wider than gaps in other portions between the substrates 74 and 75.

According to the present modification, light output to the correcting lens 46 can be adjusted not only by the lenses L1 and L2 but also by lenses which are produced by the convex portions 74a and 75a and the concave portions 74b and 75b. Accordingly, for example, an aberration of the correcting lens 46 can be further reduced.

It should be noted that the lower optical element 71 according to the present modification may have a same structure as the lower optical element 71 shown in FIG. 4. In addition, while both the substrates 74 and 75 have lenses in the present modification, alternatively, only one of the substrates may have lenses.

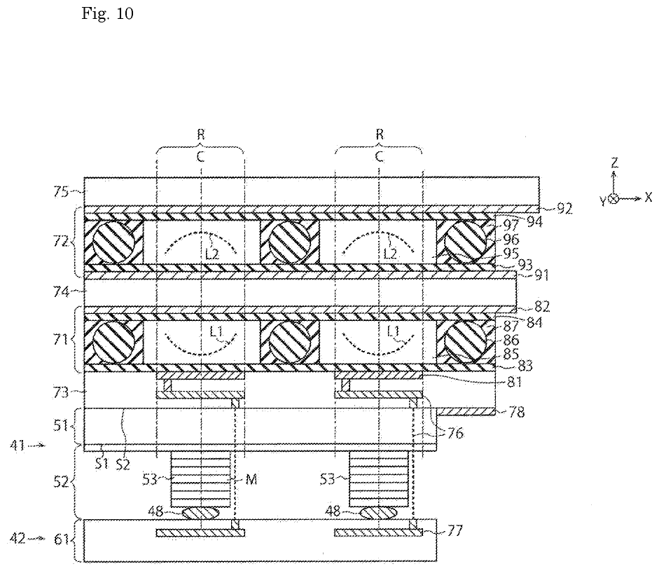

FIG. 10 is a sectional view showing a structure of the light-emitting apparatus 1 according to another modification of the first embodiment.

In the lower optical element 71 according to the present modification, the gap material 86 and the liquid crystal seal 87 are also provided between light transmission areas R. Therefore, the liquid crystal layer 85 is divided for each light-emitting element 53 and sealed so as to correspond one-to-one to the light-emitting elements 53.

In a similar manner, in the upper optical element 72 according to the present modification, the gap material 96 and the liquid crystal seal 97 are also provided between light transmission areas R. Therefore, the liquid crystal layer 95 is divided for each light-emitting element 53 and sealed so as to correspond one-to-one to the light-emitting elements 53.

According to the lower optical element 71 such as that shown in FIG. 10, for example, the liquid crystal layer 85 can be more readily controlled for each individual light-emitting element 53. In a similar manner, according to the upper optical element 72 such as that shown in FIG. 10, for example, the liquid crystal layer 95 can be more readily controlled for each individual light-emitting element 53.

On the other hand, according to the lower optical element 71 such as that shown in FIG. 4, for example, the liquid crystal layer 85 for a plurality of light-emitting elements 53 can be more readily controlled. In a similar manner, according to the upper optical element 72 such as that shown in FIG. 4, for example, the liquid crystal layer 95 for a plurality of light-emitting elements 53 can be more readily controlled. This is useful when, for example, a large lens L2 such as that shown in FIG. 4 is to be generated. Note that the lens L2 shown in FIG. 10 is a small lens in a similar manner to the lenses L1.

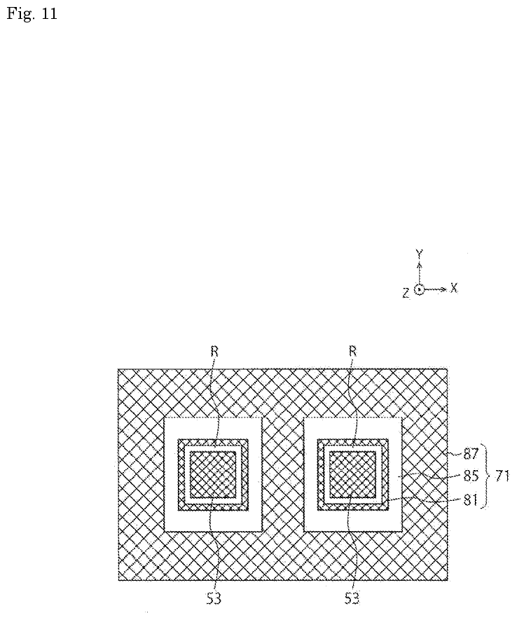

FIG. 11 is a plan view showing an example of a structure of the lower optical element 71 shown in FIG. 10.

FIG. 11 shows a positional relationship among the lower electrode 81 of the lower optical element 71, the liquid crystal layer 85, and the liquid crystal seal 87. FIG. 11 also shows positions of the light-emitting elements 53 and positions of the light transmission areas R.

In a region shown in FIG. 11, the liquid crystal layer 85 for two light-emitting elements 53 is surrounded for each light-emitting element 53 by the liquid crystal seal 87. For example, in the lower optical element 71 according to the present modification, the liquid crystal layer 85 for N-number of light-emitting elements 53 is divided into N-number of regions and sealed, where N is an integer equal to or larger than 2. In this manner, the liquid crystal layer 85 according to the present modification is divided into a plurality of regions and sealed so as to correspond one-to-one to the light-emitting elements 53, the number of the plurality of regions being the same as the number of the light-emitting elements 53. The same description applies to the upper optical element 72.

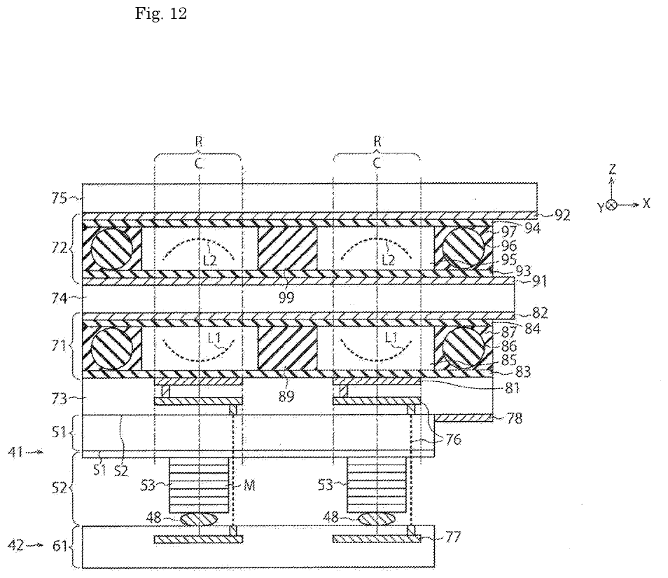

FIG. 12 is a sectional view showing a structure of the light-emitting apparatus 1 according to another modification of the first embodiment.

The lower optical element 71 according to the present modification includes a pillar 89 which is provided between the substrates 73 and 74. While the pillar 89 is provided between the light transmission areas R in a similar manner to the liquid crystal seal 87 shown in FIG. 10, the pillar 89 does not divide the liquid crystal layer 85 for each light-emitting element 53. The pillar 89 may be formed of any material as long as the material enables the gap between the substrates 73 and 74 to be adjusted.

In a similar manner, the upper optical element 72 according to the present modification includes a pillar 99 which is provided between the substrates 74 and 75. While the pillar 99 is provided between the light transmission areas R in a similar manner to the liquid crystal seal 97 shown in FIG. 10, the pillar 99 does not divide the liquid crystal layer 95 for each light-emitting element 53. The pillar 99 may be formed of any material as long as the material enables the gap between the substrates 74 and 75 to be adjusted.

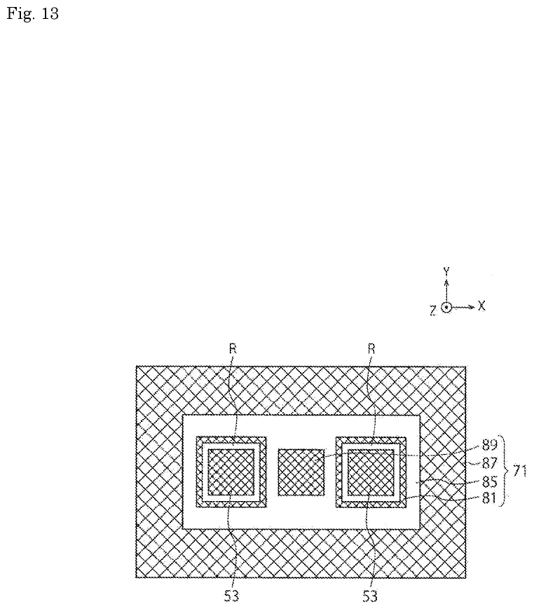

FIG. 13 is a plan view showing an example of a structure of the lower optical element 71 shown in FIG. 12.

FIG. 13 shows a positional relationship among the lower electrode 81 of the lower optical element 71, the liquid crystal layer 85, the liquid crystal seal 87, and the pillar 89. FIG. 13 also shows positions of the light-emitting elements 53 and positions of the light transmission areas R.

In a region (unit seal region) shown in FIG. 13, the liquid crystal layer 85 for two light-emitting elements 53 is surrounded in a ring shape by the liquid crystal seal 87. The lower optical element 71 according to the present modification includes such a unit seal region in plurality. For example, the lower optical element 71 according to the present modification includes four liquid crystal layers 85 for eight light-emitting elements 53 inside four unit seal regions. In this manner, the liquid crystal layers 85 according to the present modification are divided into a plurality of unit seal regions and sealed, the number of the plurality of unit seal regions being smaller than the number of the light-emitting elements 53. In addition, each unit seal region includes the pillar 89 between the light transmission areas R. The same description applies to the upper optical element 72.

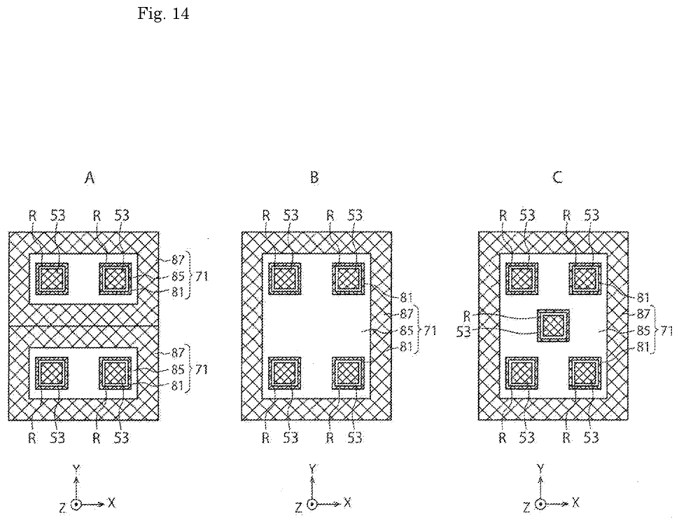

FIG. 14 is a plan view showing various examples of the structure of the lower optical element 71 shown in FIG. 4.

A in FIG. 14 shows two unit seal regions. Each unit seal region has the structure shown in FIG. 5. In A in FIG. 14, two liquid crystal layers 85 for four light-emitting elements 53 are provided inside two unit seal regions.

While B in FIG. 14 shows a region with a same size as in A in FIG. 14, the liquid crystal seal 87 between the two unit seal regions has been removed. The region shown in B in FIG. 14 can be described as a single unit seal region which is provided with a single liquid crystal layer 85 for four light-emitting elements 53. In this manner, the number of light-emitting elements 53 per unit seal region may be four instead of two. The lower optical element 71 according to the present example includes such a unit seal region.

While C in FIG. 14 shows a region with a same size as in B in FIG. 14, C in FIG. 14 further shows one light-emitting element 53 and one light transmission area R. The region shown in C in FIG. 14 can be described as a single unit seal region which is provided with a single liquid crystal layer 85 for five light-emitting elements 53. In this manner, the number of light-emitting elements 53 per unit seal region may be any number. The lower optical element 71 according to the present example includes such a unit seal region.

As described above, the light-emitting apparatus 1 according to the present embodiment includes the liquid crystal layer 85 which functions as the plurality of lenses L1 and the liquid crystal layer 95 which functions as the lens L2. Therefore, according to the present embodiment, light emitted from the plurality of light-emitting elements 53 can be suitably controlled by the lenses L1 and L2. For example, by adjusting the lenses L1 and L2, light from the light-emitting elements 53 can be suitably collimated.

### Second Embodiment

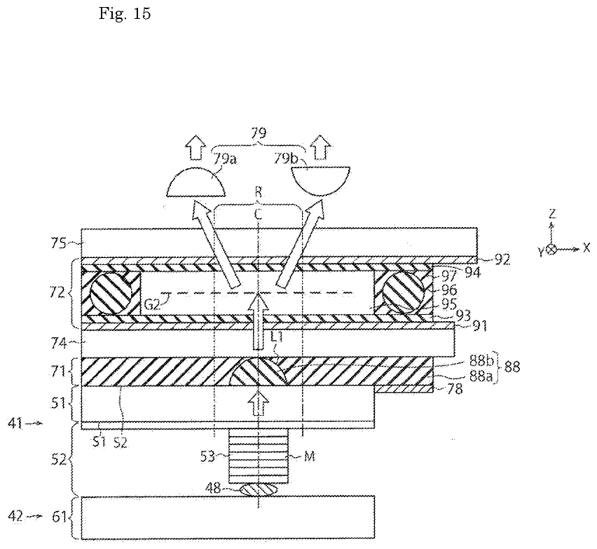

FIG. 15 is a sectional view showing a structure of a light-emitting apparatus 1 according to a second embodiment.

The light-emitting apparatus 1 according to the present embodiment has a similar structure to the light-emitting apparatus 1 shown in FIG. 8. However, the upper optical element 72 according to the present embodiment includes the liquid crystal layer 95 which functions as a diffraction grating G2. This diffraction grating G2 can also be referred to as a DOE (Diffractive Optical Element). For example, the diffraction grating G2 has a shape which alternately includes a plurality of light-shielding portions and a plurality of light-transmitting portions which extend in the Y direction.

The light-emitting apparatus 1 according to the present embodiment further includes two lenses 79a and 79b as an optical element 79 provided above the substrate 75. While the lenses 79a and 79b are, respectively, a convex lens and a concave lens in FIG. 15, the lenses 79a and 79b may be other lenses.

The diffraction grating G2 according to the present embodiment can switch between outputting light incident via a single lens L1 from a single light-emitting element 53 to the lens 79a and outputting the light to the lens 79b. For example, when a given voltage is applied to the liquid crystal layer 95, light is output from the diffraction grating G2 to the lens 79a. In addition, when another voltage is applied to the liquid crystal layer 95, light is output from the diffraction grating G2 to the lens 79b. In this manner, the diffraction grating G2 according to the present embodiment can function as a prism which controls a path of light.

In the present embodiment, the diffraction grating G2 which produces such an effect is realized by the liquid crystal layer 95. Accordingly, properties of the diffraction grating G2 can be changed by driving of the liquid crystal layer 95 (optically variable diffraction grating). For example, a width, a length, and a pitch of a light-shielding portion of the diffraction grating G2 and a width, a length, and a pitch of a light-transmitting portion of the diffraction grating G2 can be adjusted to values suitable for outputting light to the lens 79a and the lens 79b. Furthermore, by variously adjusting properties of the diffraction grating G2, the number of optical elements of the light-emitting apparatus 1 can be reduced and downsizing and weight reduction of the light-emitting apparatus 1 can be realized. In this manner, according to the present embodiment, light emitted from the light-emitting elements 53 can be suitably controlled by the diffraction grating G2 inside the liquid crystal layer 95.

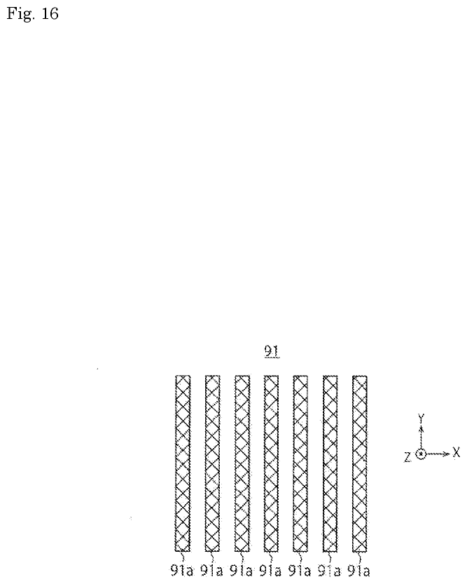

FIG. 16 is a plan view showing an example of a structure of the lower electrode 91 shown in FIG. 15. The lower electrode 91 according to the present embodiment may be structured as in this example.

In the example shown in FIG. 16, the lower electrode 91 includes a plurality of linear-shaped electrodes 91a which are arranged parallel to each other. The electrodes 91a are adjacent to each other in the X direction and extend in the Y direction. When voltage is applied to the liquid crystal layer 95 from the lower electrode 91, the diffraction grating G2 is produced inside the liquid crystal layer 95 and light incident to the diffraction grating G2 is output to the lens 79a or the lens 79b. Since the electrodes 91a are shaped so as to extend in the Y direction in a similar manner to the light-shielding portion and the light-transmitting portion of the diffraction grating G2, the electrodes 91a are suitable for generating the diffraction grating G2 inside the liquid crystal layer 95. Desirably, the electrodes 91a can be driven independently of each other. In addition, in a similar manner to the lower electrode 91 or instead of the lower electrode 91, the upper electrode 92 may be structured as in this example.

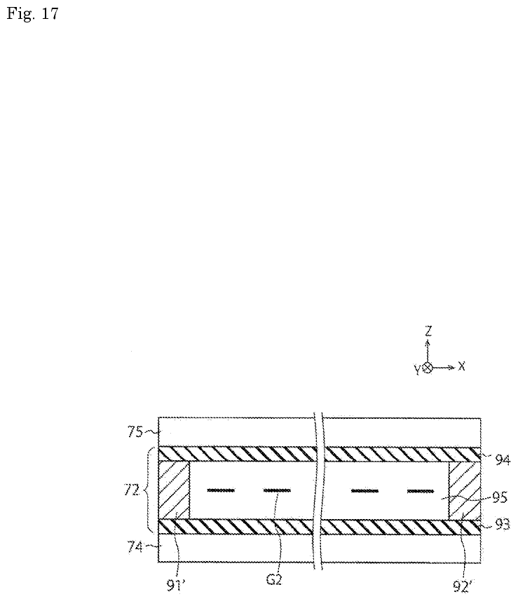

FIG. 17 is a plan view showing a structure of the upper optical element 72 according to a modification of the second embodiment.

The lower optical element 72 according to the present modification includes side electrodes 91′ and 92′ in place of the lower electrode 91 and the upper electrode 92. In contrast to the lower electrode 91 and the upper electrode 92 being arranged on the lower surface and the upper surface of the liquid crystal layer 95 so as to sandwich the liquid crystal layer 95, the side electrodes 91′ and 92′ are arranged on side surfaces of the liquid crystal layer 95 so as to sandwich the liquid crystal layer 95. The lower surface, the upper surface, and the side surfaces of the liquid crystal layer 95 are, respectively, examples of the first surface, the second surface, and the third surface of the liquid crystal layer according to the present disclosure. In the present embodiment, the side electrode 91′ is arranged on the side surface in the −X direction of the liquid crystal layer 95 and the side electrode 92′ is arranged on the side surface in the +X direction of the liquid crystal layer 95.

With the side electrodes 91′ and 92′ according to the present modification, a voltage which changes in the X direction can be applied to light advancing in the Z direction. Accordingly, for example, a direction of polarization of light can be changed by the liquid crystal layer 95. While the lower optical element 72 includes the side electrodes 91′ and 92′ in place of the lower electrode 91 and the upper electrode 92 in the present modification, alternatively, the lower optical element 72 may include the side electrodes 91′ and 92′ in addition to the lower electrode 91 and the upper electrode 92.

It should be noted that the side electrodes 91′ and 92′ according to the present modification may be configured as nontransparent electrodes instead of being configured as transparent electrodes. This is because the arrangement of the side electrodes 91′ and 92′ according to the present modification outside light transmission areas R eliminates the need for light to pass through the side electrodes 91′ and 92′.

As described above, the light-emitting apparatus 1 according to the present embodiment includes the liquid crystal layer 95 which functions as the diffraction grating G2. Therefore, according to the present embodiment, light emitted from the light-emitting elements 53 can be suitably controlled by the diffraction grating G2. For example, by adjusting the diffraction grating G2, light from the light-emitting elements 53 can be output to a position of the lens 79a and a position of the lens 79b.

It should be noted that the liquid crystal layer 95 according to the present embodiment may be controlled so as to be capable of not only outputting light from the light-emitting elements 53 to the lens 79a or the lens 79b but also shielding the light from the light-emitting elements 53 in a similar manner to the third embodiment to be described later. Accordingly, switching between outputting light to the lens 79a or the lens 79b and shielding the light can be performed.

### Third Embodiment

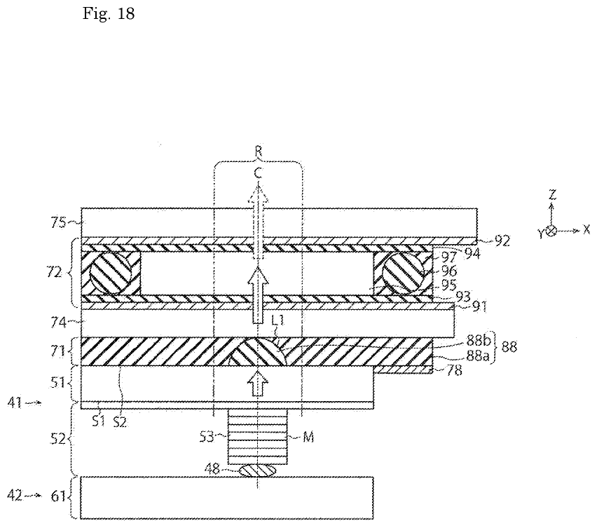

FIG. 18 is a sectional view showing a structure of a light-emitting apparatus 1 according to a third embodiment.

The light-emitting apparatus 1 according to the present embodiment has a similar structure to the light-emitting apparatus 1 shown in FIG. 8. However, the upper optical element 72 according to the present embodiment includes the liquid crystal layer 95 which functions as a light shutter.

The liquid crystal layer 95 according to the present embodiment can switch between transmitting light incident via the lens L1 from the light-emitting elements 53 and shielding the light. For example, when a given voltage is applied to the liquid crystal layer 95, a light shutter of the liquid crystal layer 95 opens and light from the lens L1 is transmitted through the liquid crystal layer 95. In addition, when another voltage is applied to the liquid crystal layer 95, the light shutter of the liquid crystal layer 95 closes and light from the lens L1 is shielded by the liquid crystal layer 95. In this case, the liquid crystal layer 95 may absorb the light from the lens L1 or reflect the light from the lens L1.

In the present embodiment, the light shutter which produces such an effect is realized by the liquid crystal layer 95. Accordingly, properties of the light shutter can be changed by driving of the liquid crystal layer 95 (optically variable light shutter). For example, light transmittance when the light shutter is open can be adjusted to a desired value. Furthermore, by variously adjusting properties of the light shutter, the number of optical elements of the light-emitting apparatus 1 can be reduced and downsizing and weight reduction of the light-emitting apparatus 1 can be realized. In this manner, according to the present embodiment, light emitted from the light-emitting elements 53 can be suitably controlled by the light shutter inside the liquid crystal layer 95.

It should be noted that shapes of the lower electrode 91 and the upper electrode 92 according to the present embodiment may be any shape as long as a light shutter can be produced inside the liquid crystal layer 95.

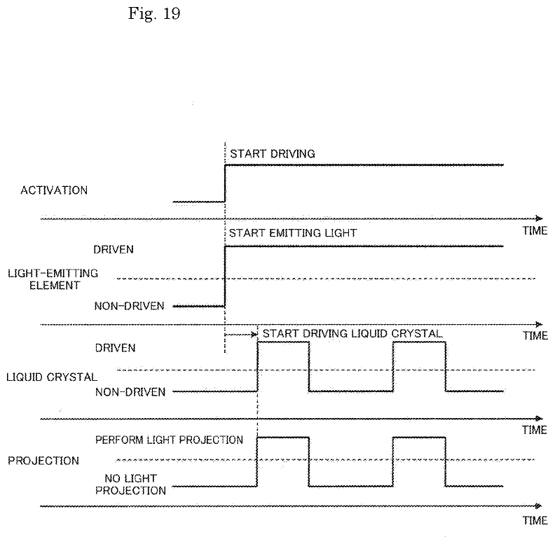

FIG. 19 is a timing chart showing an operation example of the light-emitting apparatus 1 according to the third embodiment.

FIG. 19 shows timings of activation of the light-emitting apparatus 1, driving of the light-emitting elements 53, driving of the liquid crystal layer 95, and projection of light to the subject (refer to FIG. 1). In the example shown in FIG. 19, when the light-emitting apparatus 1 is activated, the light-emitting elements 53 are continuously driven and continuously emit light. On the other hand, the liquid crystal layer 95 is controlled so that a driven state and a non-driven state are alternately repeated. As a result, the light shutter inside the liquid crystal layer 95 operates so that an on (light transmission) state and an off (light shielding) state are alternately repeated. Therefore, even if the light-emitting elements 53 continuously emit light, light projected to the subject changes so that an on state and an off state are alternately repeated. Accordingly, the subject can be irradiated with light which changes in a pulse-like manner.

As described above, the light-emitting apparatus 1 according to the present embodiment includes the liquid crystal layer 95 which functions as the light shutter. Therefore, according to the present embodiment, light emitted from the light-emitting elements 53 can be suitably controlled by the light shutter.

### Modification of First Embodiment

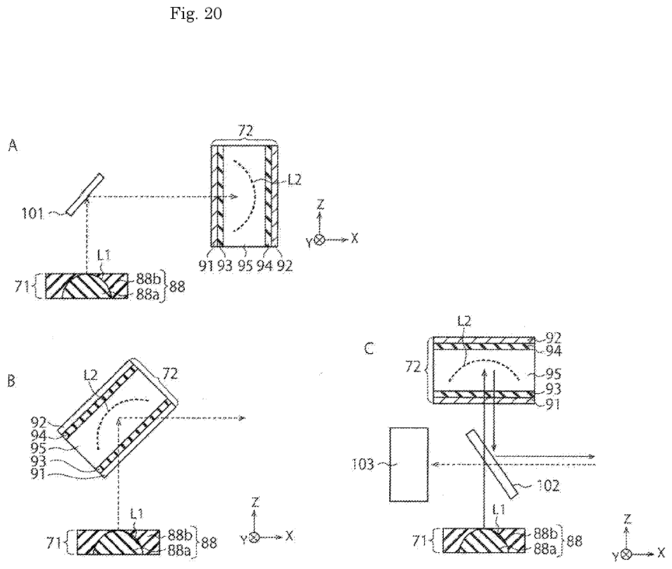

FIG. 20 is a sectional view showing a structure of the light-emitting apparatus 1 according to various modifications of the first embodiment.

In the modification shown in A in FIG. 20, the upper optical element 72 is not stacked on the lower optical element 71 but arranged at a position which is separated from the lower optical element 71. The upper optical element 72 according to the present modification receives light having passed through the first optical element 71 and reflected by a mirror 101.

Even in the modification shown in B in FIG. 20, the upper optical element 72 is not stacked on the lower optical element 71 but arranged at a position which is separated from the lower optical element 71. The upper optical element 72 according to the present modification reflects light having passed through the first optical element 71 with the liquid crystal layer 95.

Even in the modification shown in C in FIG. 20, the upper optical element 72 is not stacked on the lower optical element 71 but arranged at a position which is separated from the lower optical element 71. The upper optical element 72 according to the present modification receives light having passed through the lower optical element 71 and reflected by a mirror 102 and reflects the light with the liquid crystal layer 95. The light reflected by the liquid crystal layer 95 is reflected by the mirror 102 and radiates the subject. In addition, the light reflected by the subject is transmitted through the mirror 102 and received by a sensor 103. For example, the sensor 103 is the image sensor 21 shown in FIG. 1.

According to the modifications, for example, control of light between the lower optical element 71 and the upper optical element 72 and a positional relationship between the lower optical element 71 and the second optical element 72 can be freely designed. It should be noted that the upper optical element 72 according to the modifications need not be arranged at a position which is higher than that of the lower optical element 71. In addition, the liquid crystal layer 95 according to the modifications may function as an optical element other than the lens L2.

While the light-emitting apparatus 1 according to each embodiment or modifications thereof is used as a light source of a ranging apparatus, the light-emitting apparatus 1 may be used in other aspects. For example, the light-emitting apparatus 1 may be used as a light source of an optical device such as a printer or as a lighting apparatus.

While embodiments of the present disclosure have been described above, various modifications of the embodiments may be implemented without deviating from the gist of the present disclosure. For example, two or more embodiments may be combined and implemented.

The present disclosure can also be configured as follows.

(1)

A light-emitting apparatus, including:

a substrate;

a plurality of light-emitting elements which are provided on a side of a first surface of the substrate; and

an optical element which is provided on a side of a second surface of the substrate and into which light emitted from the plurality of light-emitting elements is incident, wherein

the optical element includes a liquid crystal layer which is configured to function as a lens.

(2)

The light-emitting apparatus according to (1), wherein

the optical element includes:

a first optical element into which light emitted from the plurality of light-emitting elements is incident; and

a second optical element into which light having passed through the first optical element is incident, wherein

at least any of the first and second optical elements includes a liquid crystal layer which is configured to function as a lens.

(3)

The light-emitting apparatus according to (2), wherein the first optical element includes a liquid crystal layer which is configured to function as a plurality of first lenses into which light emitted from the plurality of light-emitting elements is incident, and

the second optical element includes a liquid crystal layer which is configured to function as a second lens into which light having passed through the plurality of first lenses is incident.

(4)

The light-emitting apparatus according to (2), wherein the first optical element includes a liquid crystal layer which is configured to function as a plurality of first lenses into which light emitted from the plurality of light-emitting elements is incident, and

the second optical element includes a non-liquid crystal second lens into which light having passed through the plurality of first lenses is incident.

(5)

The light-emitting apparatus according to (2), wherein

the first optical element includes a plurality of non-liquid crystal first lenses into which light emitted from the plurality of light-emitting elements is incident, and the second optical element includes a liquid crystal layer which is configured to function as a second lens into which light having passed through the plurality of first lenses is incident.

(6)

The light-emitting apparatus according to (1), wherein

the optical element includes:

a first electrode which is provided on a side of the substrate of the liquid crystal layer; and

a second electrode which is provided on an opposite side to the substrate of the liquid crystal layer.

(7)

The light-emitting apparatus according to (6), wherein the first or second electrode includes a plurality of electrodes having an annular shape.

(8)

The light-emitting apparatus according to (6), wherein the first or second electrode includes a plurality of electrodes arranged in a square lattice shape.

(9)

The light-emitting apparatus according to (1), wherein

the liquid crystal layer is sandwiched between first and second substrates, and a lens is provided on a surface of at least any of the first and second substrates.

(10)

The light-emitting apparatus according to (1), wherein the liquid crystal layer is divided into a plurality of regions and sealed so as to correspond one-to-one to the plurality of light-emitting elements.

(11)

The light-emitting apparatus according to (1), wherein the liquid crystal layer is divided into a plurality of regions and sealed, the number of the plurality of regions being smaller than the number of the plurality of light-emitting elements.

(12)

The light-emitting apparatus according to (1), wherein the substrate is a semiconductor substrate containing gallium (Ga) and arsenic (As).

(13)

The light-emitting apparatus according to (1), wherein light emitted from the plurality of light-emitting elements is transmitted inside the substrate from the first surface to the second surface and is incident to the optical element.

(14)

The light-emitting apparatus according to (1), wherein the first surface of the substrate is a front surface of the substrate and the second surface of the substrate is a rear surface of the substrate.

(15)

The light-emitting apparatus according to (1), further including a drive apparatus which is provided on the side of the first surface of the substrate via the plurality of light-emitting elements and which is configured to drive the plurality of light-emitting elements.

(16)

The light-emitting apparatus according to (15), wherein the drive apparatus is configured to drive the plurality of light-emitting elements on an individual basis.

(17)

The light-emitting apparatus according to (15), wherein the drive apparatus is further configured to drive the liquid crystal layer.

(18)

The light-emitting apparatus according to (2), wherein the second optical element is configured to receive light having passed through the first optical element and reflected by a mirror, reflect light having passed through the first optical element, or receive light having passed through the first optical element and having passed through a mirror.

(19)

A light-emitting apparatus, including:

a substrate;

a light-emitting element which is provided on a side of a first surface of the substrate; and

an optical element which is provided on a side of a second surface of the substrate and into which light emitted from the light-emitting element is incident, wherein the optical element includes a liquid crystal layer which is configured to function as a diffraction grating.

(20)

The light-emitting apparatus according to (19), wherein

the optical element includes:

a first electrode which is provided on a side of the substrate of the liquid crystal layer; and

a second electrode which is provided on an opposite side to the substrate of the liquid crystal layer.

(21)

The light-emitting apparatus according to (20), wherein the first or second electrode includes a plurality of line-shaped electrodes which are arranged parallel to each other.

(22)

The light-emitting apparatus according to (19), wherein

the liquid crystal layer has a first surface which is positioned on a side of the substrate, a second surface which is positioned on an opposite side to the substrate, and a third surface which is positioned between the first surface and the second surface, and

the optical element includes first and second electrodes which are provided so as to sandwich the liquid crystal layer on the third surface of the liquid crystal layer.

(23)

A light-emitting apparatus, including;

a substrate;

a light-emitting element which is provided on a side of a first surface of the substrate; and

an optical element which is provided on a side of a second surface of the substrate and into which light emitted from the light-emitting element is incident, wherein the optical element includes a liquid crystal layer which is configured to function as a light shutter.

(24)

The light-emitting apparatus according to (23), wherein the light-emitting apparatus controls on/off of light emitted from the light-emitting apparatus by controlling on/off of the light shutter while continuously emitting light from the light-emitting element.

### REFERENCE SIGNS LIST

1 Light-emitting apparatus

2 Imaging apparatus

3 Control apparatus

11 Light-emitting unit

12 Drive circuit

13 Power source circuit

14 Light-emitting side optical system

21 Image sensor

22 Image processing unit

23 Imaging-side optical system

31 Ranging unit

41 LD chip

42 LDD substrate

43 Mounting substrate

44 Heat dissipation substrate

45 Correcting lens holding unit

46 Correcting lens

47 Wiring

48 Bump

51 Substrate

52 Laminated film

53 Light-emitting element

54 Anode electrode

55 Cathode electrode

61 Substrate

62 Connection pad

71 Lower optical element

72 Upper optical element

73, 74, 75 Substrate

74a, 75a Convex portion

74b, 75b Concave portion

76 Wiring

77 Liquid crystal drive unit

78 Liquid crystal drive element

79 Optical element

79a, 79b Lens

81 Lower electrode

81a, 81b Electrode

82 Upper electrode

83 Lower oriented film

84 Upper oriented film

85 Liquid crystal layer

86 Gap material

87 Liquid crystal seal

88 Lens film

88a First lens film

88b Second lens film

89 Pillar

91 Lower electrode

91′ Side electrode

91a Electrode

92 Upper electrode

92′ Side electrode

93 Lower oriented film

94 Upper oriented film

95 Liquid crystal layer

96 Gap material

97 Liquid crystal seal

98 Lens film

99 Pillar

101 Mirror

102 Mirror

103 Sensor

What is claimed is:

1. A light-emitting apparatus, comprising:
a substrate;
a plurality of light-emitting elements which are provided on a side of a first surface of the substrate; and
an optical element which is provided on a side of a second surface of the substrate and into which light emitted from the plurality of light-emitting elements is incident, wherein
the optical element includes a liquid crystal layer which is configured to function as a lens.

2. The light-emitting apparatus according to claim 1, wherein
the optical element includes:
a first optical element into which light emitted from the plurality of light-emitting elements is incident; and
a second optical element into which light having passed through the first optical element is incident, wherein
at least any of the first and second optical elements includes a liquid crystal layer which is configured to function as a lens.

3. The light-emitting apparatus according to claim 2, wherein
the first optical element includes a liquid crystal layer which is configured to function as a plurality of first lenses into which light emitted from the plurality of light-emitting elements is incident, and
the second optical element includes a liquid crystal layer which is configured to function as a second lens into which light having passed through the plurality of first lenses is incident.

4. The light-emitting apparatus according to claim 2, wherein
the first optical element includes a liquid crystal layer which is configured to function as a plurality of first lenses into which light emitted from the plurality of light-emitting elements is incident, and
the second optical element includes a non-liquid crystal second lens into which light having passed through the plurality of first lenses is incident.

5. The light-emitting apparatus according to claim 2, wherein
the first optical element includes a plurality of non-liquid crystal first lenses into which light emitted from the plurality of light-emitting elements is incident, and
the second optical element includes a liquid crystal layer which is configured to function as a second lens into which light having passed through the plurality of first lenses is incident.

6. The light-emitting apparatus according to claim 1, wherein
the optical element includes:
a first electrode which is provided on a side of the substrate of the liquid crystal layer; and
a second electrode which is provided on an opposite side to the substrate of the liquid crystal layer.

7. The light-emitting apparatus according to claim 6, wherein the first or second electrode includes a plurality of electrodes having an annular shape.

8. The light-emitting apparatus according to claim 6, wherein the first or second electrode includes a plurality of electrodes arranged in a square lattice shape.

9. The light-emitting apparatus according to claim 1, wherein
the liquid crystal layer is sandwiched between first and second substrates, and
lens is provided on a surface of at least any of the first and second substrates.

10. The light-emitting apparatus according to claim 1, wherein the liquid crystal layer is divided into a plurality of regions and sealed so as to correspond one-to-one to the plurality of light-emitting elements.

11. The light-emitting apparatus according to claim 1, wherein the liquid crystal layer is divided into a plurality of regions and sealed, the number of the plurality of regions being smaller than the number of the plurality of light-emitting elements.

12. The light-emitting apparatus according to claim 1, wherein the substrate is a semiconductor substrate containing gallium (Ga) and arsenic (As).

13. The light-emitting apparatus according to claim 1, wherein light emitted from the plurality of light-emitting elements is transmitted inside the substrate from the first surface to the second surface and is incident to the optical element.

14. The light-emitting apparatus according to claim 1, wherein the first surface of the substrate is a front surface of the substrate and the second surface of the substrate is a rear surface of the substrate.

15. The light-emitting apparatus according to claim 1, further comprising a drive apparatus which is provided on the side of the first surface of the substrate via the plurality of light-emitting elements and which is configured to drive the plurality of light-emitting elements.

16. The light-emitting apparatus according to claim 15, wherein the drive apparatus is configured to drive the plurality of light-emitting elements on an individual basis.

17. The light-emitting apparatus according to claim 15, wherein the drive apparatus is further configured to drive the liquid crystal layer.

18. The light-emitting apparatus according to claim 2, wherein the second optical element is configured to receive light having passed through the first optical element and reflected by a mirror, reflect light having passed through the first optical element, or receive light having passed through the first optical element and having passed through a mirror.

19. A light-emitting apparatus, comprising:
a substrate;
a light-emitting element which is provided on a side of a first surface of the substrate; and
an optical element which is provided on a side of a second surface of the substrate and into which light emitted from the light-emitting element is incident, wherein
the optical element includes a liquid crystal layer which is configured to function as a diffraction grating.

20. The light-emitting apparatus according to claim 19, wherein
the optical element includes:
a first electrode which is provided on a side of the substrate of the liquid crystal layer; and
a second electrode which is provided on an opposite side to the substrate of the liquid crystal layer.

21. The light-emitting apparatus according to claim 20, wherein the first or second electrode includes a plurality of line-shaped electrodes which are arranged parallel to each other.

22. The light-emitting apparatus according to claim 19, wherein
the liquid crystal layer has a first surface which is positioned on a side of the substrate, a second surface which is positioned on an opposite side to the substrate, and a third surface which is positioned between the first surface and the second surface, and
the optical element includes first and second electrodes which are provided so as to sandwich the liquid crystal layer on the third surface of the liquid crystal layer.

23. A light-emitting apparatus, comprising:
a substrate;
a light-emitting element which is provided on a side of a first surface of the substrate; and
an optical element which is provided on a side of a second surface of the substrate and into which light emitted from the light-emitting element is incident, wherein
the optical element includes a liquid crystal layer which is configured to function as a light shutter.

21. The light-emitting apparatus according to claim 23, wherein the light-emitting apparatus controls on/off of light emitted from the light-emitting apparatus by controlling on/off of the light shutter while continuously emitting light from the light-emitting element.
